(19) United States
(12) Patent Application Publication
(10) Pub. No.: US 2026/0043837 A1
(43) Pub. Date: Feb. 12, 2026

(54) METHOD AND SYSTEM FOR PREDICTING TLP TRIGGER VOLTAGE, 2ND BREAKDOWN VOLTAGE AND HOLDING VOLTAGE

(71) Applicant: AIP Technology Corporation, Grand Cayman (KY)

(72) Inventors: Tung-Yang CHEN, Zhubei City (TW); Chang-Lin WU, ZhuBei City (TW)

(73) Assignee: AIP Technology Corporation, Grand Cayman (KY)

(21) Appl. No.: 18/918,595

(22) Filed: Oct. 17, 2024

(30) Foreign Application Priority Data
Aug. 8, 2024 (TW) 113129810

(51) Int. Cl. G01R 31/00; G06N 3/08

(52) U.S. Cl. CPC G01R 31/002; G06N 3/08

(57) ABSTRACT

Disclosed is a method and system for predicting TLP trigger voltage, 2nd breakdown voltage and holding voltage. The method includes: converting a plurality of measurement data into characteristic curves based on time series. The characteristic curves include a voltage-time curve, a current-time curve and a leakage current-time curve. After inputting the characteristic curves into a trigger voltage prediction model and a 2nd breakdown voltage prediction model respectively, the trigger voltage and 2nd breakdown voltage can be predicted respectively. The trigger voltage and 2nd breakdown voltage are used to calculate a holding voltage. Finally, marking points of the trigger voltage, 2nd breakdown voltage and holding voltage are marked on the current-voltage characteristic curve (I-V curve), and displayed on a display device.

### BACKGROUND OF THE INVENTION

This application claims priority for the TW patent application no. 113129810 filed on 8 Aug. 2024, the content of which is incorporated by reference in its entirely.

### Field of the Invention

The invention relates to a data processing method and system in the field of electrostatic discharge detection (ESD) technology, in particular, to a transmission line pulse (TLP) data processing.

### Description of the Prior Art

In the prior art, electrostatic discharge testing is another method commonly used to evaluate the performance of a protective element, for example, the protective element is a transient voltage suppressor (TVS). ESD testing simulates real-world electrostatic events, such as the human body test (HBM), to determine the response and effectiveness of protective elements when faced with such events. However, ESD testing also has some shortcomings. For example, it may not provide enough information to fully describe all important characteristics of the protective element, and may ignore some key performance indicators, such as clamping voltage and leakage current etc.

The key parameters that characterize the performance of ESD protective elements include trigger voltage (Vt1), holding voltage (Vh) and 2nd breakdown current (It2). In order to determine the characteristics of the protective element, the technicians will further use the transmission line pulse test to interpret the key parameters from the transmission line pulse data. The interpretation method is often to manually interpret the three key parameters based on empirical rules, or to write the empirical rules into an interpretation program and use a computer program to find the key parameters in each data from multiple measurement data. Due to the huge amount of measurement data, manual interpretation is inefficient and may result in human misjudgment. For example, the trigger voltage is a turning point on the current-voltage curve, but noise may cause a small turning point in the curve, resulting in misjudgment. Although the empirical rules can be written into programs to improve the efficiency in interpreting key parameters, the program interpretation still cannot effectively filter out the noise in the measurement data, so there is still a certain probability that the wrong key parameters will be found. As shown in TLP test diagram in FIG. 1, due to the influence of noise, a very small voltage reflex is generated, and the wrong turning point is shown as Vt1=0.626 (the triangle mark in the figure), but the correct trigger voltage should be 34.5122528 (the square mark in the figure). In addition, the prior art also cannot indicate these on the curve graph.

In view of this, for the above-mentioned deficiencies of the conventional technology and future needs, the invention provides a method and system for predicting TLP trigger voltage, 2nd breakdown voltage and holding voltage. The specific architecture and its implementation will be described in detail below.

### BRIEF SUMMARY OF THE INVENTION

One main objective of the invention is to provide a method and system for predicting TLP trigger voltage, 2nd breakdown voltage and holding voltage, which converts each of the TLP measurement data into characteristic curves of a voltage, a current, and a leakage current, and marks the trigger voltage, the 2nd breakdown voltage and the holding voltage in the characteristic curves through a judgment process for neural network model to train; a prediction model trained in this way may accurately predict the trigger voltage and the 2nd breakdown voltage, and further derive the holding voltage, which may solve the problem of easy error in program interpretation in the prior art.

The other objective of the invention is to train the trigger voltage prediction model and the 2nd breakdown voltage prediction model, and use an optimizer and a loss function to compile the prediction model to maximize or minimize the loss function and improve the accuracy of the prediction model.

In order to achieve the above objectives, the invention provides a method for predicting TLP trigger voltage, 2nd breakdown voltage and holding voltage, which is suitable for a processing device to perform calculations and predictions. The method includes steps of: converting a plurality of TLP measurement data into a plurality of characteristic curves based on time series, wherein the characteristic curves include a voltage-time curve, a current-time curve and a leakage current-time curve, and the measurement data are measured using transmission line pulses; inputting the characteristic curves into a trigger voltage prediction model to predict a trigger voltage, and inputting the characteristic curves into a 2nd breakdown voltage prediction model to predict a 2nd breakdown voltage; deriving a holding voltage based on the trigger voltage and the 2nd breakdown voltage; and marking marking points of the trigger voltage, the 2nd breakdown voltage and the holding voltage on a current-voltage characteristic curve formed by the measurement data and displaying the marked current-voltage characteristic curve on a display device.

According to an embodiment of the invention, the measurement data is a data set of the current-voltage characteristic curve (I-V curve) obtained from the outside.

According to an embodiment of the invention, a method for establishing the trigger voltage prediction model and the 2nd breakdown voltage prediction model includes steps of: subjecting the measurement data to a data pre-processing to convert each of the measurement data into the characteristic curves, and marking a preset trigger voltage and a preset holding voltage in the characteristic curves; dividing the measurement data into a training set and a validation set, using the training set to train a neural network model, and using an optimizer adjust a plurality of model parameters of the neural network model and outputting the trigger voltage prediction model and the 2nd breakdown voltage prediction model; using the trigger voltage prediction model to predict a trigger voltage of the validation set, and using the 2nd breakdown voltage prediction model to predict a 2nd breakdown voltage of the validation set, so as to adjust parameters of the trigger voltage prediction model and the 2nd breakdown voltage prediction model; calculating a holding voltage of the verification set by using the predicted trigger voltage of the validation set and the predicted 2nd breakdown voltage of the validation set, so as to evaluate a performance of the trigger voltage prediction model and the 2nd breakdown voltage prediction model through the predicted.

According to an embodiment of the invention, the data pre-processing includes steps of: determining an accuracy of each of the measurement data and filtering out incorrect measurement data; retrieving the current-voltage characteristic curve and a leakage current field; determining whether a leakage current value in the leakage current field meets a current value of a breakdown condition sequentially according to an increasing plurality of voltage values in the current-voltage characteristic curve; setting a current value as a 2nd breakdown current if the current value that meets breakdown conditions is found, and setting a last current value in the measurement data as the 2nd breakdown current if the current value that meets the breakdown conditions is not found; and finding a first turning point in the current-voltage characteristic curve as a temporary trigger voltage according to the voltage value and the current value corresponding to the 2nd breakdown current.

According to an embodiment of the invention, a voltage value at a timing point next to the first turning point is used as a temporary holding voltage.

According to an embodiment of the invention, the data pre-processing further includes steps of: finding a minimum voltage value in a time period between the timing point of the temporary holding voltage and a last timing point as the preset holding voltage.

According to an embodiment of the invention, the data pre-processing further includes steps of: finding a maximum voltage value in a time period between the timing point of the preset holding voltage and a timing point of the temporary trigger voltage as the preset trigger voltage.

According to an embodiment of the invention, the step of using the training set to train the trigger voltage prediction model and the 2nd breakdown voltage prediction model includes steps of: dividing the measurement data into the training set and a test set; inputting the characteristic curves, the preset trigger voltage and the preset holding voltage of each of the measurement data in the training set into the neural network model for training; and using the test set to test, wherein when a performance evaluation is greater than a preset value, the trigger voltage prediction model and the 2nd breakdown voltage prediction model are established.

According to an embodiment of the invention, the step of inputting the characteristic curves, the preset trigger voltage and the preset holding voltage of each of the measurement data in the training set into the neural network model for training further includes steps of: loading a plurality of pre-trained parameters into the neural network model and using the training set to train the neural network model; storing an accuracy rate and a loss rate of each round of training; stopping training the neural network model when all the measurement data in the training set have been trained; and using the optimizer to adjust a plurality of model parameters of the neural network model to maximize or minimize a loss function.

According to an embodiment of the invention, the step of calculating the holding voltage of the validation set by using the predicted trigger voltage of the validation set and the predicted 2nd breakdown voltage of the validation set further includes steps of: finding a minimum voltage value between a timing point of the trigger voltage of the validation set and a timing point of the 2nd breakdown voltage of the validation set as the holding voltage of the validation set.

The invention further provides a system for predicting TLP trigger voltage, 2nd breakdown voltage and holding voltage, which is suitable for a processing device to perform calculations and predictions. The system includes: a data conversion module, configured to convert a plurality of TLP measurement data into a plurality of characteristic curves based on time series, wherein the characteristic curves include a voltage-time curve, a current-time curve and a leakage current-time curve, and the measurement data are measured using transmission line pulses; a prediction module, configured to execute a trigger voltage prediction model and a 2nd breakdown voltage prediction model to input the characteristic curves into a trigger voltage prediction model to predict a trigger voltage, and input the characteristic curves into a 2nd breakdown voltage prediction model to predict a 2nd breakdown voltage; and an operation module, connected with the prediction model and configured to derive a holding voltage based on the trigger voltage and the 2nd breakdown voltage and mark marking points of the trigger voltage, the 2nd breakdown voltage and the holding voltage on a current-voltage characteristic curve formed by the measurement data and display the marked current-voltage characteristic curve on a display device.

According to an embodiment of the invention, the system further includes a pre-processing module, which is connected with the data conversion module to pre-process the measured data first before training the trigger voltage prediction model and the 2nd breakdown voltage prediction model, so as to mark a preset trigger voltage and a preset holding voltage in the characteristic curves of each of the measurement data.

According to an embodiment of the invention, the system further includes a model training module, which is connected with the pre-processing module, and is configured to: divide the measurement data into a training set and a validation set, use the training set to train the trigger voltage prediction model and the 2nd breakdown voltage prediction model, and then use the trigger voltage prediction model to predict a trigger voltage of the validation set and use the 2nd breakdown voltage prediction model to predict a 2nd breakdown voltage of the validation set, so as to adjust parameters of the trigger voltage prediction model and the 2nd breakdown voltage prediction model; to calculate a holding voltage of the verification set by using the predicted trigger voltage of the validation set and the predicted 2nd breakdown voltage of the validation set, so as to evaluate a performance of the trigger voltage prediction model and the 2nd breakdown voltage prediction model through the predicted.

According to an embodiment of the invention, the neural network model includes: a normalized layer, configured to use the measurement data to perform fitting to normalize the data, and subject the measurement data and the data of the 2nd breakdown voltage data and the trigger voltage therein to a data pre-processing to convert into an N×3 matrix suitable for the specifications of the neural network model, wherein N is the number of timing points included in the measurement data, and 3 represents the voltage value, the current value and the leakage current value; a first one-dimensional convolutional layer, configured to receive the N×3 matrix, and output an A₁×B₁ matrix after training with a predefined plurality of filters, wherein B1 is the number of the filters, and A₁ represents the number of weight values included in each of the filters; a second one-dimensional convolutional layer, configured to receive the A₁×B₁ matrix, and output an A₂×B₂ matrix after training with a predefined plurality of filters, wherein B₂ is the number of the filters, and A2 represents the number of weight values included in each of the filters; a maximum pooling layer, configured to subject the A₂×B₂ matrix a data compression; and a full-connected layer, configured to use the sigmoid function to convert values of the A₂×B₂ matrix into values between 0 and 1, and output a 1×n matrix, where n<B2.

According to an embodiment of the invention, the neural network model further includes a dropout layer connected to the maximum pooling layer and the full-connected layer.

According to an embodiment of the invention, after the full-connected layer outputs the 1×n matrix, the model training module uses an optimizer to adjust the plurality of model parameters of the neural network model to maximize or minimize a loss function.

According to an embodiment of the invention, the optimizer is configured to use an adaptive moment estimation algorithm, and the loss function is a mean square error.

### BRIEF DESCRIPTION OF THE DRAWINGS

FIG. 1 is a current-voltage curve graph of a transmission line pulse in the prior art of the invention, wherein the program misinterprets a trigger voltage.

FIG. 2 is a block diagram showing a system for predicting TLP trigger voltage, 2nd breakdown voltage and holding voltage according to the invention.

FIG. 3 is a flow chart of a method for predicting TLP trigger voltage, 2nd breakdown voltage and holding voltage according to the invention.

FIG. 4 is a graph of a voltage-time curve, a current-time curve and a leakage current-time curve converted from a current-voltage characteristic curve.

FIG. 5 is a flow chart of a method for establishing a trigger voltage prediction model and a 2nd breakdown voltage prediction model according to the invention.

FIG. 6 is a detailed flow chart of step S20 in FIG. 5.

FIG. 7 is a detailed flow chart of step S22 in FIG. 5.

FIGS. 8 to 12 are diagrams of an embodiment of a neural network architecture according to the invention.

FIG. 13 is a diagram showing prediction points in a matrix.

FIG. 14 is a diagram of using the method and system for predicting TLP trigger voltage, 2nd breakdown voltage and holding voltage according to the invention to predict and mark TLP trigger voltage, 2nd breakdown voltage and holding voltage.

### DETAILED DESCRIPTION OF THE INVENTION

Clear and complete description will be made to the technical solutions in embodiments of the present invention in conjunction with drawings in the embodiments of the present invention hereafter. Obviously, the described embodiments are merely a part of embodiments of the present invention and not all the embodiments.

It is understood that the terms “comprises” and “includes” when used in the specification and the appended claims indicates the presence of features, entireties, steps, operations, elements, and/or components described while the presence or addition of one or more other features, entireties, steps, operations, elements, components and/or combinations thereof are not excluded.

It is also understood that the terms used herein is for the purpose of describing particular embodiments and is not intended to be limiting the present invention. As used in the specification and the appended claims of the invention, the singular forms of “a”, “one” and “the” are intended to include the plural forms, unless the context clearly indicates otherwise.

It is further understood that the term “and/or” used in the specification and the appended claims refers to any combination of one or more of the associated listed items and all possible combinations, and includes such combinations.

In view of the defect that the prior art is prone to errors in interpreting key parameters such as trigger voltage, 2nd breakdown voltage and holding voltage from TLP measurement data, the invention proposes the following implementation method to solve the above defects.

### Glossary

Descriptions of TLP element characteristics: key parameters that characterize the performance of ESD protective elements: trigger voltage/current (Vt1, It1), holding voltage/current (Vh, Ih), 2nd breakdown voltage/current (Vt2, It2), instantaneous on-resistance (Ron), which are described in detail as below.

Transmission line pulse data: including voltage-current characteristics and leakage values generated when a plurality of transmission line pulses are applied to the protective element, wherein the voltage-current characteristics may be plotted as a current-voltage curve (I-V curve), and the leakage value may help determine the 2nd breakdown voltage and current of the protection element.

Trigger point (Vt1): represents the highest voltage reached by the protective element at the beginning of operation.

Holding point (Vh): is the holding voltage applied to the device under test, and is usually within the operating voltage range of the device under test.

2nd breakdown point (Vt2/It2): refers to the 2nd breakdown phenomenon that occurs in the protected electronic element during ESD testing. When the protected electronic element experiences the 1st breakdown, the voltage continues to rise, and when it reaches the 2nd breakdown point, more severe voltage fluctuations and possible permanent damage will occur.

The invention provides a method and system for predicting TLP trigger voltage, 2nd breakdown voltage and holding voltage. Its implementation will be described in detail below.

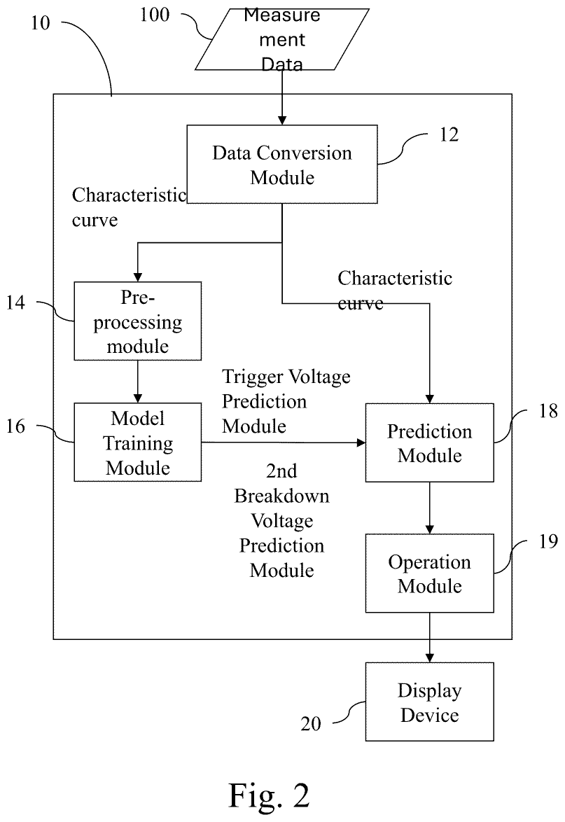

With reference to FIG. 2, the system 10 for predicting TLP trigger voltage, 2nd breakdown voltage and holding voltage according to the invention is installed in a processing device for receiving a data set of TLP measurement data 100, training a prediction model according to the measurement data 100, and predicting key parameters of TLP by using a prediction model. The system 10 for predicting TLP trigger voltage, 2nd breakdown voltage and holding voltage includes a data conversion module 12, a pre-processing module 14, a model training model 16, a prediction model 18 and an operation module 19. The data conversion module 12 is connected with the pre-processing module 14 and the prediction module 18. The pre-processing module 14 is further connected with the model training module 16. The prediction module 18 is further connected with the operation module 19. The pre-processing module 14 and the model training module 16 are configured to train a trigger voltage prediction model and a 2nd breakdown voltage prediction model. The prediction module 18 and the operation module 19 actually apply the two trained prediction models to respectively predict the trigger voltage and the 2nd breakdown voltage, and further operation to obtain the holding voltage.

In the invention, the processing device may be, for example, a computer device having a computing processing capability. The data conversion module 12, the pre-processing module 14, the model training module 16, the prediction module 18 and the operation module 19 are hardware or hardware-software components with data and/or image processing capabilities, such as computer devices, cloud servers or barebones, which have components such as a central processing unit (CPU), a graphics processing unit (GPU), and memory, or a microcontroller unit (MCU) that has integrated the necessary members. The data conversion module 12 may be, for example, a component having data receiving or communication capabilities, and the data conversion module 12 may receive external transmission line pulse data through a wired or wireless interface, such as receiving transmission line pulse data from a TLP measurement machine. The TLP measurement machine may be, for example, ESDEMC TLP-1000, HANWA HED T-5000 or Thermo Scientific Celestron. The operation module 19 may further be a component having input/output (I/O) and data transmission capabilities, so as to display the prediction result on a display device 20. The display device 20 is a screen or a touch screen.

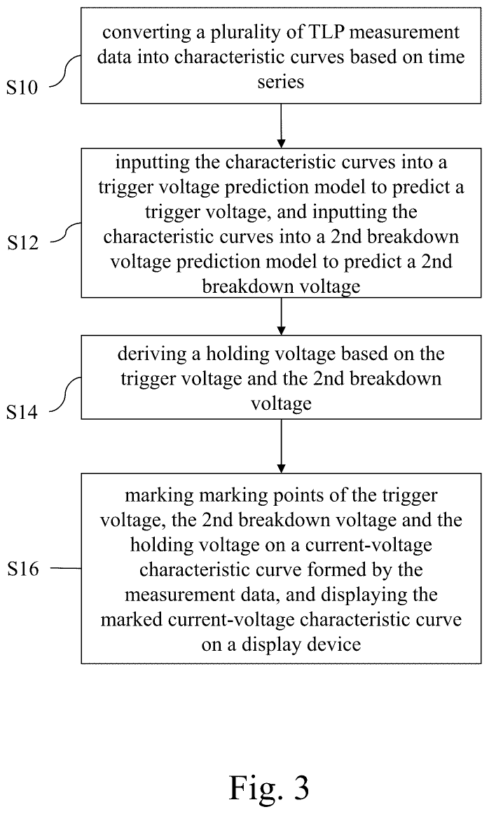

The following first describes the actual process of using the trigger voltage prediction model and the 2nd breakdown voltage prediction model. Please also refer to the flow chart in FIG. 3.

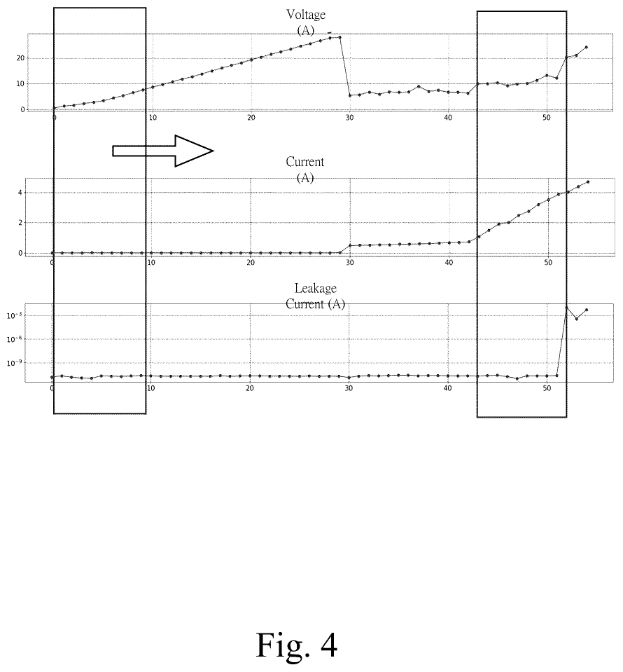

The TLP measurement data 100 includes three data fields: current, voltage, and leakage current. Each data field includes multiple data. These data are obtained by measuring a pulse wave with a voltage increasing from small to large. The data are listed in the data field according to the measurement time. Therefore, the measurement data 100 belongs to time series data. When the measurement data 100 enters the system 10 for predicting TLP trigger voltage, 2nd breakdown voltage and holding voltage according to the invention, in the step S10, the data conversion module 12 may convert the three data fields of the measurement data 100 into a characteristic curve according to the time series respectively, wherein the voltage data field is converted into a voltage-time curve, the current data field is converted into a current-time curve, and the leakage current data field is converted into a leakage current-time curve, as shown in FIG. 4. Next, as described in the step S12, the prediction module 12 is configured to execute a trigger voltage prediction model and a 2nd breakdown voltage prediction model to input the characteristic curves into the trigger voltage prediction model to predict a trigger voltage Vt1, and further input the characteristic curves into the 2nd breakdown voltage prediction model to predict a 2nd breakdown voltage Vt2. In the step S14, the operation module 19 receives the trigger voltage Vt1 and the 2nd breakdown voltage Vt2 predicted by the prediction module 18, and calculates and derives a holding voltage Vh from the known trigger voltage Vt1 and the 2nd breakdown voltage Vt2. Finally, as described in the step S16, the operation module 19 is configured to mark marking points of the trigger voltage Vt1, the 2nd breakdown voltage Vt2 and the holding voltage Vh on a current-voltage characteristic curve formed by the measurement data 100, and displaying the marked current-voltage characteristic curve on a display device 20.

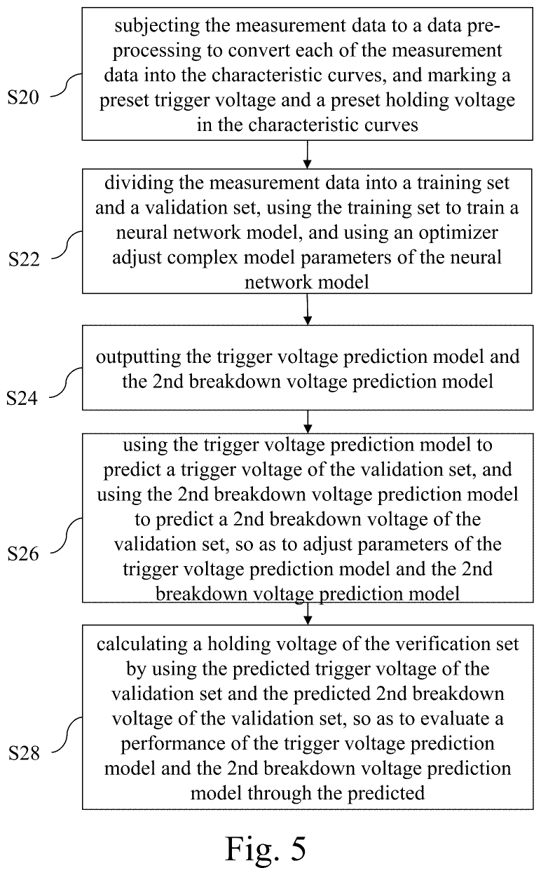

The following describes a method of training and establishing the trigger voltage prediction model and the 2nd breakdown voltage prediction model. Please also refer to the flow chart in FIG. 5. As described in the step S20, first the measurement data 100 is subjected to a data pre-processing, which includes filtering out incorrect data with the data conversion module 12, converting each of the measurement data into the characteristic curve as shown in FIG. 4, and marking a preset trigger voltage and a preset holding voltage from the characteristic curves with the pre-processing module 14 for subsequent model training. Then the steps S22 to S28 are all performed in the model training module 16. In the step S22, first the measurement data 100 are divided into a training set and a validation set, the training set is used to train a neural network model, and an optimizer is used adjust a plurality of model parameters of the neural network model and then the trigger voltage prediction model and the 2nd breakdown voltage prediction model are output in the step S24. The step S26 is a step of using the validation set to adjust the parameters of the two trained models, using the trigger voltage prediction model to predict a trigger voltage of the validation set and using the 2nd breakdown voltage prediction model to predict a 2nd breakdown voltage of the validation set. Since the trigger voltage and the 2nd breakdown voltage in the validation set are known, the parameters of the trigger voltage prediction model and the 2nd breakdown voltage prediction model may be adjusted by comparing the predicted trigger voltage and the predicted 2nd breakdown voltage of the validation set with the actual trigger voltage and the actual 2nd breakdown voltage of the validation set. In the step S28, a holding voltage of the verification set is calculated by using the predicted trigger voltage of the validation set and the predicted 2nd breakdown voltage of the validation set, so as to evaluate a performance of the trigger voltage prediction model and the 2nd breakdown voltage prediction model through the predicted. In the step S28, after the holding voltage of the validation set is calculated, the holding voltage is compared with the actually-known holding voltage of the validation set to obtain an accuracy of the validation set, and then evaluate the accuracy of the trigger voltage prediction model and the 2nd breakdown voltage prediction model, i.e., the performance of the trigger voltage prediction model and the 2nd breakdown voltage prediction model. Further, the holding voltage of the validation set found in the step S28 is to find a minimum voltage value between a timing point of the trigger voltage of the validation set and a timing point of the 2nd breakdown voltage of the validation set.

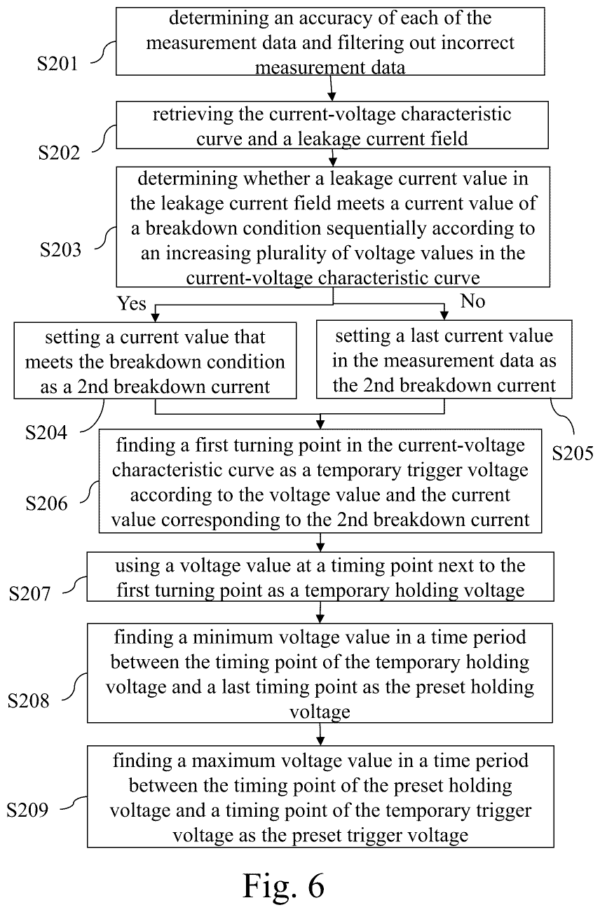

Please refer to FIG. 6 for the detailed flow chart of the step S20.

In the process of the data pre-processing, as described in the step S201, first, the accuracy of each of the measurement data is determined 100%, and incorrect measurement data is filtered out, wherein for example, if the transmission line interface is not properly connected, the characteristic curve will be a straight line without any changes, which is incorrect data; or if the curve suddenly rises when the voltage applied is still very small at the beginning, the data is also incorrect data and needs to be filtered out. Next, as described in the steps S202 to S203, the current-voltage characteristic curve and the leakage current field are retrieved from the measurement data 100, and whether any leakage current value in the leakage current field meets a breakdown condition is determined in sequence according to the increasing voltage value in the current-voltage characteristic curve. If there is any leakage current value in the leakage current field that meets the breakdown condition, as described in the step S204, the current value corresponding to the leakage current value that meets the breakdown condition is set as a 2nd breakdown current It2; if no current value that meets the breakdown condition is found, then as described in step S205, the last current value in the measurement data is set as the 2nd breakdown current It2. Subsequently, in the step S206, a first turning point in the current-voltage characteristic curve is found as a temporary trigger voltage according to the voltage value and the current value corresponding to the 2nd breakdown current It2. In the step S207, a voltage value at a timing point next to the first turning point is used as a temporary holding voltage. Next, as described in the steps S208 to S209, a minimum voltage value in a time period between the timing point of the temporary holding voltage and a last timing point is found as the preset holding voltage. A maximum voltage value in a time period between the timing point of the preset holding voltage and a timing point of the temporary trigger voltage is found as the preset trigger voltage. The minimum voltage value and the maximum voltage value are also turning points in the characteristic curve. At this point, the data pre-processing has obtained the 2nd breakdown current, the preset holding voltage and the preset trigger voltage. These three points are marked and the values of these marked points are used to train the neural network model.

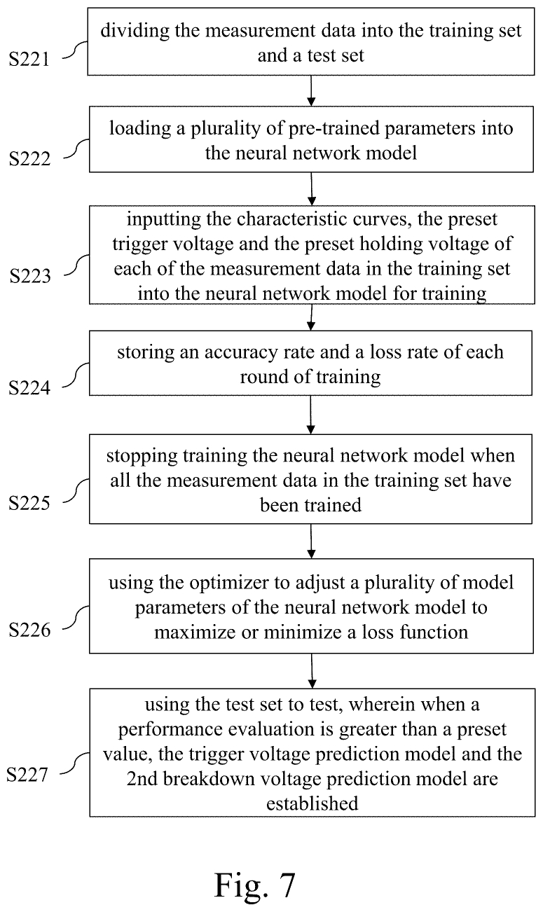

Please refer to FIG. 7 for the detailed flow chart of the step S22 of FIG. 5 regarding training the neural network model.

Step S221, the measurement data are divided into the training set and a test set. For example, If there are 100 measurement data, 70 of the measurement data are used as the training set, 20 as the test set, and 10 as the validation set. Step S222, a plurality of pre-trained parameters are loaded into the neural network model. Step S223, the characteristic curves of each of the measurement data in the training set and the preset trigger voltage and the preset holding voltage obtained in the above steps S208-S209 are input into the neural network model for training, and after each round of training and validation, an accuracy data and a loss rate are stored, as described in the step S224. Next, step S225, training the neural network model is stopped when all the measurement data in the training set have been trained. Step S226, the optimizer is used to adjust a plurality of model parameters of the neural network model to maximize or minimize a loss function. Finally, as described in the step S227, the test set is used to test, wherein when a performance evaluation is greater than a preset value, the trigger voltage prediction model and the 2nd breakdown voltage prediction model are established.

In an embodiment, the neural network model adopts a one-dimensional convolutional neural network (1D CNN), but is not limited to adopting only one-dimensional convolutional neural networks. The following uses a one-dimensional convolutional neural network to illustrate the architecture of the neural network model.

When an one-dimensional convolutional neural network processes signal data, it may encounter many different patterns, which may have different lengths and positions. The one-dimensional convolutional neural networks may effectively identify patterns in signal data in feature analysis, even if the positions of these patterns in the data are not fixed. The one-dimensional convolutional neural network may capture these patterns in shorter snippets of the entire data set and combine them in higher layers to generate more complex features. In particular, when processing time series signals, the one-dimensional convolutional neural networks may detect and analyze important features in the signal, such as frequency changes, amplitude changes, or other patterns. Similarly, the one-dimensional convolutional neural networks are also suitable for signal data with fixed-length periods, such as audio signals, because the one-dimensional convolutional neural networks may effectively extract features from these periodic patterns. The invention applies multiple one-dimensional filters to perform convolution operations on the input data. When the filters slide on the data, the weighted sum of the local area is calculated to generate a feature map. The convolution operations may capture local patterns and features in data; taking FIG. 4 as an example, the frame on the characteristic curve refers to the size of the scanning frame set by the filter, and a sliding step size during scanning may be further set. If no setting is made, the default step size is 1. In other words, the scanning frame will shift and scan from the frame of the front part of FIG. 4 to the frame of the back part one by one, which is equivalent to scanning from the beginning to the end. Each time a frame is scanned, a weighted value of the local area may be obtained. After scanning from the beginning to the end, all weighted values are summed up to obtain the feature map.

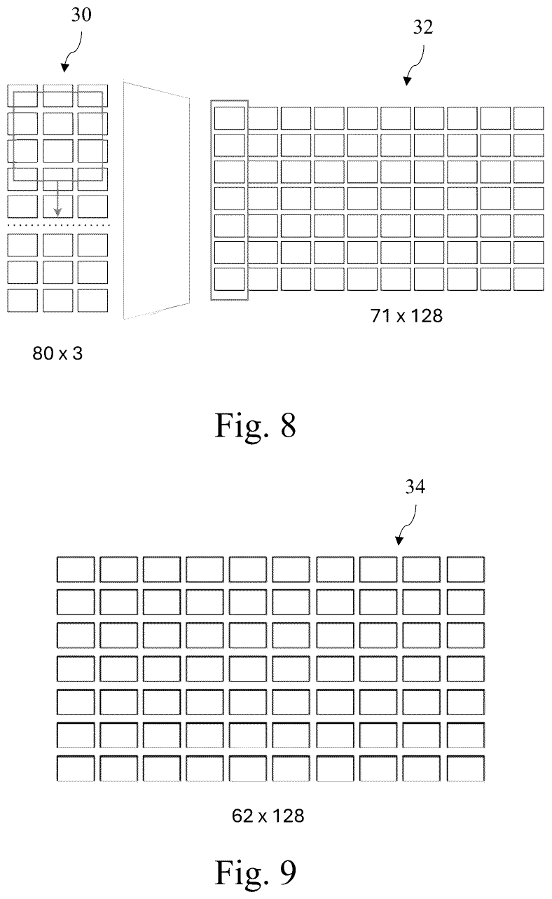

When the neural network model is an one-dimensional convolutional neural network model, the model includes a normalized layer, a first one-dimensional convolutional layer, a second one-dimensional convolutional layer, a maximum pooling layer, a dropout layer and a full-connected layer. Please also refer to FIGS. 8 to 11 for detailed description of the function of each layer.

The normalized layer 30 uses the measurement data for normalization so that the data have a zero mean and a unit variance. As shown in FIG. 8, the normalized layer 30 is configured to subject the measurement data and the data of the 2nd breakdown voltage data and the trigger voltage therein to a data pre-processing to convert into an N×3 matrix suitable for the specifications of the neural network model, wherein N is the number of timing points included in the measurement data, and 3 represents three values (the voltage value, the current value and the leakage current value). Assuming that each of the measurement data contains 80 timing points, then in each time interval, the three data of the voltage, the current and the leakage current measured by TLP are stored, so that the 803 matrix shown in FIG. 8 may be obtained. N may also be set to 100 or other numbers, and the part less than 100 is filled with the value of the last timing point. Next, the measurement data are divided into the training set and the test set. For example, the train_test_split( ) function is used to divide the measurement data into the training set and the test set.

The first one-dimensional convolutional layer 32 is connected with the normalized layer 30. The first one-dimensional convolutional layer 32 receives the N×3 matrix and outputs an A₁×B₁ matrix after training with a predefined plurality of filters, wherein the height of the filter is defined as 10, i.e., the three characteristic curves are scanned in batches every 10 time points, and features are learned from the three characteristic curves respectively; taking FIG. 4 as an example, the leakage current-time curve will remain flat continuously, and the leakage current will suddenly increase after the breakdown, which is the feature that the first one-dimensional convolution layer 32 needs to learn from the leakage current-time curve. B₁ is the number of the filters, and A₁ represents the number of weight values contained in each of the filters. Each of the filters may be trained to produce one feature. If the number of filters is too small, the accuracy will decrease. In an embodiment shown in FIG. 8, a 71×128 matrix is shown, which means that 128 features may be obtained after training the first one-dimensional convolutional layer 32. If the number of weights does not reach the number of A₁, for example, there are only 65, the remaining 6 values are filled with the value of the last point. In the embodiment, with the filter size defined and considering the length of the input matrix, the optimal case is that each of the filters contains 71 weight values.

The second one-dimensional convolutional layer 34 is connected with the first one-dimensional convolutional layer 32. The second one-dimensional convolutional layer 34 has the same logic as the first one-dimensional convolution layer 32. The second one-dimensional convolutional layer is configured to receive the A₁×B₁ matrix, and output an A₂×B₂ matrix after training with a predefined plurality of filters, wherein B₂ is the number of the filters, and A₂ represents the number of weight values included in each of the filters. In some embodiments, B₂=B₁. In an embodiment shown in FIG. 9, the 71×128 matrix is trained by the second one-dimensional convolutional layer 34 to output a 62×128 matrix.

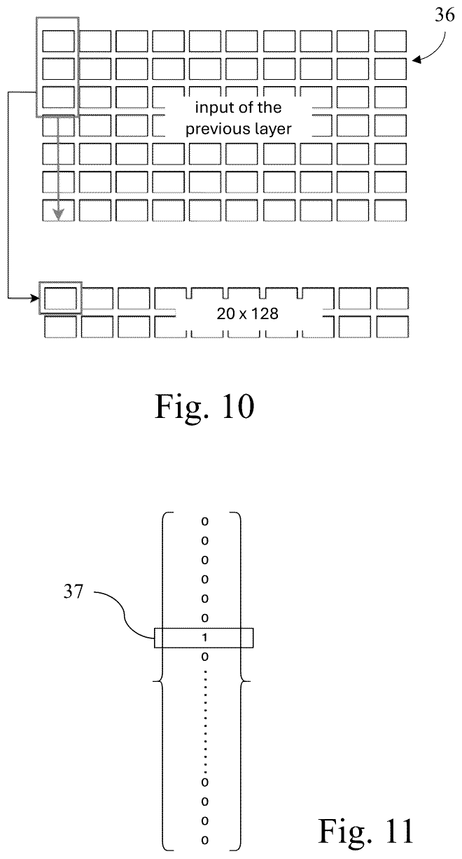

The maximum pooling layer 36 is connected with the second one-dimensional convolutional layer 34. The maximum pooling layer 36 is configured to compress the data, reduce the dimension of the features and retain important information, which may speed up the operation efficiency and prevent overfitting of the data. The pooling layer is often used after the convolution layers. As shown in FIG. 10, in an embodiment of the invention, the maximum pooling layer 36 compresses the 62×128 matrix to obtain a 20×128 matrix.

The dropout layer (not shown) is connected with the maximum pooling layer 36. The dropout layer randomly assigns zero weights to neurons in the network. Since a ratio of 0.1 is chosen, 10% of the neurons will have a weight value of zero. Through the above operations, the network will not be too sensitive to small changes in the data. Therefore, the dropout layer may reduce the overfitting problem.

The data processing during training includes a marking method. Assuming that there are n timing points, when the correct trigger voltage Vt1 (or the 2nd breakdown voltage Vt2) is calibrated, the storage is performed in a 1×n matrix. As shown in FIG. 11, the values of the 1st to 6th points are all 0, and the value of the 7th point is 1, so the 7th point is marked as the correct marking point 37.

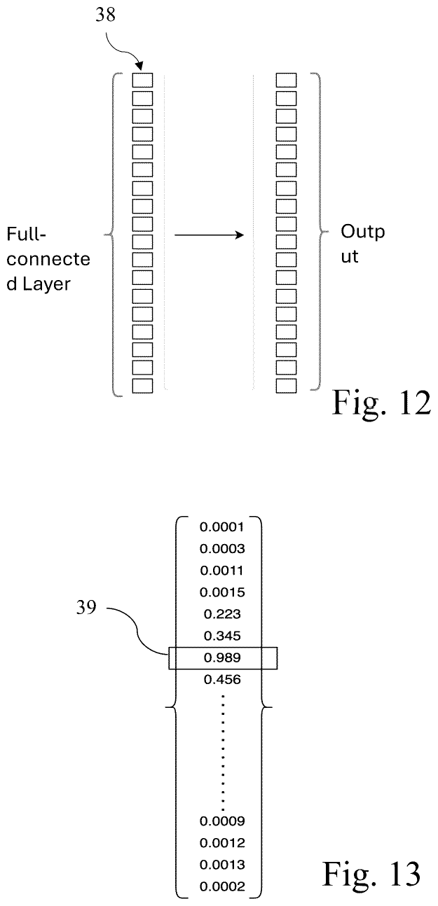

The full-connected layer 38 is connected with the dropout layer. Since the marking method is designed as shown in FIG. 11, the full-connected layer 38 is activated by the sigmoid function to convert the A₂×B₂ matrix into the 1×n matrix for outputting, wherein n<B₂ and each value is between 0 and 1. As shown in FIG. 12, the point of the maximum value is the prediction point. For example, when predicting the 2nd breakdown voltage Vt2, the point with the highest probability of being the prediction point is the point of the 2nd breakdown voltage Vt2. Taking FIG. 13 as an example, the maximum value in the 1×n matrix is the value of the 7th point, 0.989, so the 7th point is the prediction point 39.

Next, the model training model will use the optimizer to adjust the model parameters of the neural network model to maximize or minimize a loss function. During training, the goal is to minimize the loss function. The loss function is used to measure the gap between the prediction value of the model and the actual target value. In other words, the loss function defines how good the model is. The optimizer may calculate the weights and bias values for each layer, usually through a gradient descent algorithm. The optimizer calculates the gradient of the loss function with respect to the model parameters, and then changes the weights of the neural network based on these gradients. This operation is repeated over multiple training iterations, with the optimizer constantly adjusting the direction and number of steps to find the target point so that the gap between the prediction value and the true target value continues to narrow.

More specifically, after the trigger voltage prediction model and the 2nd breakdown voltage prediction model predict the trigger voltage Vt1 and the 2nd breakdown voltage Vt2, the model training module will use the loss function to calculate the difference between the prediction results and the actual results. Finally, the optimizer is used to update the parameters of the model so that this difference is reduced on the next prediction. This process is repeated in multiple training iterations until the performance of the trigger voltage prediction model and the 2nd breakdown voltage prediction model reaches a satisfactory level.

In an embodiment of the invention, the optimizer is configured to use an adaptive moment estimation algorithm, and the loss function is a mean square error (MSE). The adaptive moment estimation is an optimization algorithm for deep learning models that combines two extended stochastic gradient descent methods, including Root Mean Square Propagation and Momentum. When updating the weights, the Adam optimizer considers not only the first-order moment estimation of the gradient (i.e., the gradient itself, which is related to Momentum), but also the second-order moment estimation (i.e., the square of the gradient, which is related to RMSProp). These two moment estimations are exponentially decaying moving averages, so Adam will perform bias correction on the gradient to make the gradient smoother.

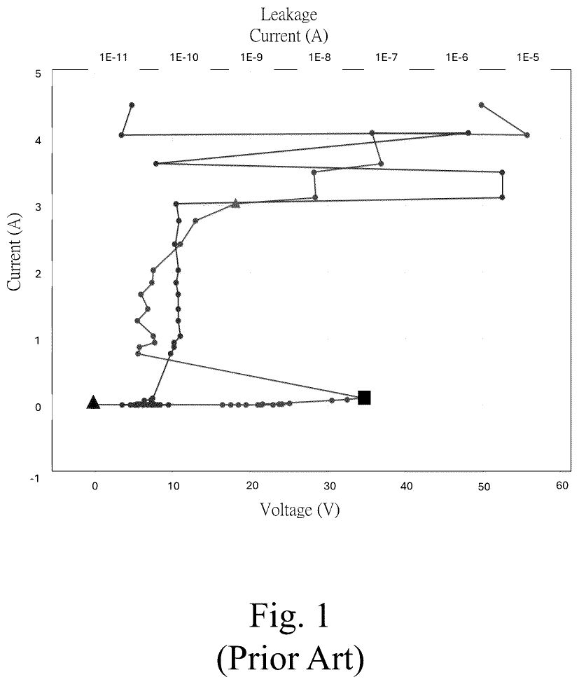

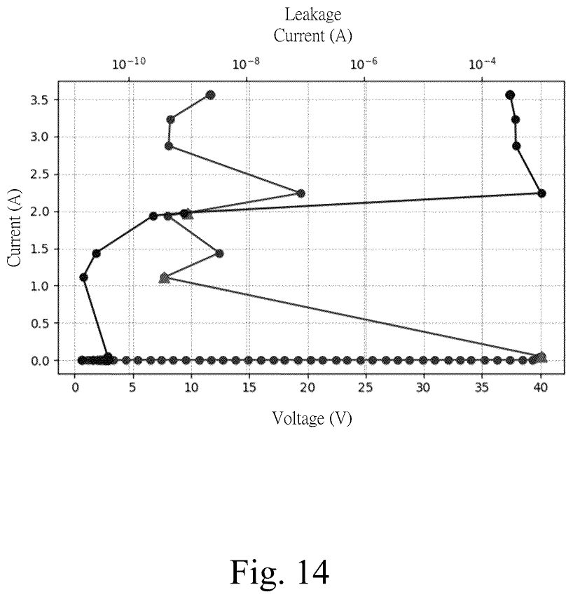

FIG. 14 is a diagram of using the method and system for predicting TLP trigger voltage, 2nd breakdown voltage and holding voltage according to the invention to predict and mark TLP trigger voltage, 2nd breakdown voltage and holding voltage. After predicting the trigger voltage Vt1, the 2nd breakdown voltage Vt2 and calculating the holding voltage Vh, the system marks the trigger voltage Vt1, the 2nd breakdown voltage Vt2 and the holding voltage Vh on the current-voltage characteristic curve formed by the measurement data, as shown in FIG. 12. Compared with the prior art shown in FIG. 1, the method and system for predicting TLP trigger voltage, 2nd breakdown voltage and holding voltage according to the invention may not only correctly predict the key parameters of TLP, but also mark and indicate which parameters are on the voltage-current curve, and display them so that users can intuitively see the three marked points representing the trigger voltage Vt1, the 2nd breakdown voltage Vt2 and the holding voltage Vh.

The above mentioned is only the preferred embodiments of the present invention and is not intended to limit the scope of the implementation of the present invention. Therefore, any equivalent changes or modifications made according to the features and spirit described within the scope of the present invention should be included within the claims of the present invention.

What is claimed is:

1. A method for predicting transmission line pulse (TLP) trigger voltage, 2nd breakdown voltage and holding voltage, suitable for a processing device to perform calculations and prediction, the method comprising steps of:
converting a plurality of measurement data into characteristic curves based on time series, wherein the characteristic curves comprise a voltage-time curve, a current-time curve and a leakage current-time curve, and the plurality of measurement data are measured using TLPs;
inputting the characteristic curves into a trigger voltage prediction model to predict a trigger voltage, and inputting the characteristic curves into a 2nd breakdown voltage prediction model to predict a 2nd breakdown voltage;
deriving a holding voltage based on the trigger voltage and the 2nd breakdown voltage; and
marking marking points of the trigger voltage, the 2nd breakdown voltage and the holding voltage on a current-voltage characteristic curve formed by the plurality of measurement data, and displaying the marked current-voltage characteristic curve on a display device.

2. The method for predicting TLP trigger voltage, 2nd breakdown voltage and holding voltage according claim 1, wherein the plurality of measurement data is a data set of the current-voltage characteristic curves obtained from the outside.

3. The method for predicting TLP trigger voltage, 2nd breakdown voltage and holding voltage according claim 1, wherein a method for establishing the trigger voltage prediction model and the 2nd breakdown voltage prediction model comprises steps of:
subjecting the plurality of measurement data to a data pre-processing to convert each of the plurality of measurement data into the characteristic curves, and marking a preset trigger voltage and a preset holding voltage in the characteristic curves;
dividing the plurality of measurement data into a training set and a validation set, using the training set to train a neural network model, and using an optimizer adjust a plurality of model parameters of the neural network model and outputting the trigger voltage prediction model and the 2nd breakdown voltage prediction model;
using the trigger voltage prediction model to predict a trigger voltage of the validation set, and using the 2nd breakdown voltage prediction model to predict a 2nd breakdown voltage of the validation set, so as to adjust parameters of the trigger voltage prediction model and the 2nd breakdown voltage prediction model;
calculating a holding voltage of the verification set by using the predicted trigger voltage of the validation set and the predicted 2nd breakdown voltage of the validation set, so as to evaluate a performance of the trigger voltage prediction model and the 2nd breakdown voltage prediction model through the predicted.

4. The method for predicting TLP trigger voltage, 2nd breakdown voltage and holding voltage according claim 3, wherein the data pre-processing comprises steps of:
determining an accuracy of each of the plurality of measurement data and filtering out incorrect measurement data of the plurality of measurement data;
retrieving the current-voltage characteristic curve and a leakage current field;
determining whether a leakage current value in the leakage current field meets a current value of a breakdown condition sequentially according to an increasing plurality of voltage values in the current-voltage characteristic curve;
setting a current value as a 2nd breakdown current if the current value that meets breakdown conditions is found, and set a last current value in the plurality of measurement data as the 2nd breakdown current if the current value that meets the breakdown conditions is not found; and
finding a first turning point in the current-voltage characteristic curve as a temporary trigger voltage according to the voltage value and the current value corresponding to the 2nd breakdown current.

5. The method for predicting TLP trigger voltage, 2nd breakdown voltage and holding voltage according claim 4, wherein a voltage value at a timing point next to the first turning point is used as a temporary holding voltage.

6. The method for predicting TLP trigger voltage, 2nd breakdown voltage and holding voltage according claim 5, wherein the data pre-processing further comprises steps of:
finding a minimum voltage value in a time period between the timing point of the temporary holding voltage and a last timing point as the preset holding voltage.

7. The method for predicting TLP trigger voltage, 2nd breakdown voltage and holding voltage according claim 6, wherein the data pre-processing further comprises steps of:
finding a maximum voltage value in a time period between the timing point of the preset holding voltage and a timing point of the temporary trigger voltage as the preset trigger voltage.

8. The method for predicting TLP trigger voltage, 2nd breakdown voltage and holding voltage according claim 3, wherein the step of using the training set to train the trigger voltage prediction model and the 2nd breakdown voltage prediction model comprises steps of:
dividing the plurality of measurement data into the training set and a test set;
inputting the characteristic curves, the preset trigger voltage and the preset holding voltage of each of the plurality of measurement data in the training set into the neural network model for training; and
using the test set to test, wherein when a performance evaluation is greater than a preset value, the trigger voltage prediction model and the 2nd breakdown voltage prediction model are established.

9. The method for predicting TLP trigger voltage, 2nd breakdown voltage and holding voltage according claim 8, wherein the step of inputting the characteristic curves, the preset trigger voltage and the preset holding voltage of each of the plurality of measurement data in the training set into the neural network model for training further comprises steps of:
loading a plurality of pre-trained parameters into the neural network model and using the training set to train the neural network model;
storing an accuracy rate and a loss rate of each round of training;
stopping training the neural network model when all the plurality of measurement data in the training set have been trained; and
using the optimizer to adjust a plurality of model parameters of the neural network model to maximize or minimize a loss function.

10. The method for predicting TLP trigger voltage, 2nd breakdown voltage and holding voltage according claim 3, wherein the step of calculating the holding voltage of the validation set by using the predicted trigger voltage of the validation set and the predicted 2nd breakdown voltage of the validation set further comprises steps of:
finding a minimum voltage value between a timing point of the trigger voltage of the validation set and a timing point of the 2nd breakdown voltage of the validation set as the holding voltage of the validation set.

11. A system for predicting TLP trigger voltage, 2nd breakdown voltage and holding voltage, suitable for a processing device to perform calculations and predictions, comprising:
a data conversion module, configured to convert a plurality of measurement data into characteristic curves based on time series, wherein the characteristic curves comprise a voltage-time curve, a current-time curve and a leakage current-time curve, and the plurality of measurement data are measured using transmission line pulses;
a prediction module, configured to execute a trigger voltage prediction model and a 2nd breakdown voltage prediction model to input the characteristic curves into the trigger voltage prediction model to predict a trigger voltage, and inputting the characteristic curves into the 2nd breakdown voltage prediction model to predict a 2nd breakdown voltage; and
an operation module, connected with the prediction module, configured to use the trigger voltage and the 2nd breakdown voltage to calculate and derive a holding voltage, and to mark marking points of the trigger voltage, the 2nd breakdown voltage and the holding voltage on a current-voltage characteristic curve formed by the plurality of measurement data and display the marked current-voltage characteristic curve on a display device.

12. The system for predicting TLP trigger voltage, 2nd breakdown voltage and holding voltage according claim 11, wherein the plurality of measurement data is a data set of the current-voltage characteristic curves obtained from the outside.

13. The system for predicting TLP trigger voltage, 2nd breakdown voltage and holding voltage according claim 11, further comprising a pre-processing module, which is connected with the data conversion module to pre-process the measured data first before training the trigger voltage prediction model and the 2nd breakdown voltage prediction model, so as to mark a preset trigger voltage and a preset holding voltage in the characteristic curves of each of the plurality of measurement data.

14. The system for predicting TLP trigger voltage, 2nd breakdown voltage and holding voltage according claim 13, wherein the pre-processing module is configured to determine the correctness of each of the measurement data, and retrieve the current-voltage characteristic curve and a leakage current field after filtering out incorrect measurement data of the plurality of measurement data;
determine whether a leakage current value in the leakage current field meets a current value of a breakdown condition sequentially according to an increasing plurality of voltage values in the current-voltage characteristic curve;
set a current value as a 2nd breakdown current if the current value that meets breakdown conditions is found, and set a last current value in the plurality of measurement data as the 2nd breakdown current if the current value that meets the breakdown conditions is not found; and
find a first turning point in the current-voltage characteristic curve as a temporary trigger voltage according to the voltage value and the current value corresponding to the 2nd breakdown current.

15. The system for predicting TLP trigger voltage, 2nd breakdown voltage and holding voltage according claim 14, wherein a voltage value at a timing point next to the first turning point is used as a temporary holding voltage.

16. The system for predicting TLP trigger voltage, 2nd breakdown voltage and holding voltage according claim 15, wherein the pre-processing module is further configured to find a minimum voltage value in a time period between the timing point of the temporary holding voltage and a last timing point as the preset holding voltage, and find a maximum voltage value in a time period between the timing point of the preset holding voltage and a timing point of the temporary trigger voltage as the preset trigger voltage.

17. The system for predicting TLP trigger voltage, 2nd breakdown voltage and holding voltage according claim 13, further comprising a model training module, which is connected with the pre-processing module, and is configured to: divide the plurality of measurement data into a training set and a validation set, use the training set to train the trigger voltage prediction model and the 2nd breakdown voltage prediction model, and then use the trigger voltage prediction model to predict a trigger voltage of the validation set and use the 2nd breakdown voltage prediction model to predict a 2nd breakdown voltage of the validation set, so as to adjust parameters of the trigger voltage prediction model and the 2nd breakdown voltage prediction model; to calculate a holding voltage of the verification set by using the predicted trigger voltage of the validation set and the predicted 2nd breakdown voltage of the validation set, so as to evaluate a performance of the trigger voltage prediction model and the 2nd breakdown voltage prediction model through the predicted.

18. The system for predicting TLP trigger voltage, 2nd breakdown voltage and holding voltage according claim 17, wherein the model training module is configured to: divide the plurality of measurement data into the training set and a test set; to load a plurality of pre-trained parameters into the neural network model, input the characteristic curves, the preset trigger voltage and the preset holding voltage of each of the plurality of measurement data in the training set into the neural network model for training, and store an accuracy rate and a loss rate of each round of training; to stop training the neural network model when all the plurality of measurement data in the training set have been trained; and to use the test set to test, wherein when a performance evaluation is greater than a preset value, the trigger voltage prediction model and the 2nd breakdown voltage prediction model are established.

19. The system for predicting TLP trigger voltage, 2nd breakdown voltage and holding voltage according claim 17, wherein the model training module is configured to find a minimum voltage value between a timing point of the trigger voltage of the validation set and a timing point of the 2nd breakdown voltage of the validation set as a holding voltage of the validation set by using the predicted trigger voltage of the validation set and the predicted 2nd breakdown voltage of the validation set.

20. The system for predicting TLP trigger voltage, 2nd breakdown voltage and holding voltage according claim 9, wherein the neural network model comprises:
a normalized layer, configured to use the plurality of measurement data to perform fitting to normalize the data, and subject the plurality of measurement data and the data of the 2nd breakdown voltage data and the trigger voltage therein to a data pre-processing to convert into an N×3 matrix suitable for the specifications of the neural network model, wherein N is the number of timing points included in the plurality of measurement data, and 3 represents the voltage value, the current value and the leakage current value;
a first one-dimensional convolutional layer, configured to receive the N×3 matrix, and output an A₁ ×B₁ matrix after training with a predefined plurality of filters, wherein B₁ is the number of the filters, and A₁ represents the number of weight values included in each of the filters;
a second one-dimensional convolutional layer, configured to receive the A₁ ×B₁ matrix, and output an A₂ ×B₂ matrix after training with a predefined plurality of filters, wherein B₂ is the number of the filters, and A₂ represents the number of weight values included in each of the filters;
a maximum pooling layer, configured to subject the A₂ ×B₂ matrix a data compression; and
a full-connected layer, configured to use the sigmoid function to convert values of the A₂ ×B₂ matrix into values between 0 and 1, and output a 1×n matrix, where n<B₂.

21. The system for predicting TLP trigger voltage, 2nd breakdown voltage and holding voltage according claim 20, wherein the neural network model further comprises a dropout layer connected to the maximum pooling layer and the full-connected layer.

22. The system for predicting TLP trigger voltage, 2nd breakdown voltage and holding voltage according claim 20, wherein after the full-connected layer outputs the 1×n matrix, the model training module uses an optimizer to adjust the plurality of model parameters of the neural network model to maximize or minimize a loss function.

23. The system for predicting TLP trigger voltage, 2nd breakdown voltage and holding voltage according claim 20, wherein the optimizer is configured to use an adaptive moment estimation algorithm, and the loss function is a mean square error.
